(19) United States
(12) Patent Application Publication
(10) Pub. No.: US 2015/0114466 A1
(43) Pub. Date: Apr. 30, 2015

(54) CIGS Solar Cell Having Flexible Substrate Based on Improved Supply of Na and Fabrication Method Thereof

(71) Applicant: Korea Institute of Energy Research, Daejeon (KR)

(72) Inventors: SeoungKyu Ahn, Daejeon (KR); Kyung Hoon Yoon, Daejeon (KR); Jae Ho Yun, Daejeon (KR); Jun Sik Cho, Daejeon (KR); SeJin Ahn, Daejeon (KR); Jihye Gwak, Daejeon (KR); Kee Shik Shin, Daejeon (KR); Kihwan Kim, Daejeon (KR); Joo Hyung Park, Daejeon (KR); Young Joo Eo, Daejeon (KR); Jin-Su Yoo, Seoul (KR); Ara Cho, Seoul (KR)

(21) Appl. No.: 14/389,884

(22) PCT Filed: Aug. 5, 2013
(86) PCT No.: PCT/KR2013/007044

§ 371 Date: Oct. 1, 2014

(30) Foreign Application Priority Data
Aug. 9, 2012 (KR) 10-2012-0087075

(51) Int. Cl. H01L 31/0749; H01L 31/18

(52) U.S. Cl. CPC H01L 31/0749; H01L 31/18
USPC 136/262; 438/69

(57) ABSTRACT

A CIGS solar cell having a flexible substrate based on improved supply of Na. The CIGS solar cell includes a substrate formed of a flexible material, a rear electrode formed on the substrate, a CIGS light-absorption layer formed on the rear electrode, a buffer layer formed on the CIGS light-absorption layer, and a front electrode formed on the buffer layer, wherein the rear electrode comprise a single-layered Na-added metal electrode layer. A single-layered Na-added Mo electrode layer, specific resistance of which is about 1/10th the specific resistance under conditions of a process of forming a typical multilayer rear electrode, is applied to the rear electrode, thereby providing a CIGS solar cell having a flexible substrate and high conversion efficiency.

### TECHNICAL FIELD

The present invention relates to a CIGS solar cell having a flexible substrate, and more particularly, to a CIGS solar cell having a flexible substrate based on improved supply of Na to a light-absorption layer, and a fabrication method thereof.

### BACKGROUND ART

Recently, importance on development of next-generation clean energy sources has increased due to the depletion of fossil fuel reserves. Thereamong, a solar cell is a device that converts sunlight directly into electricity. Solar cells can serve as an energy source to solve energy problems in the future, since they do not emit pollutants, have semi-permanent lifespan and utilize unlimited energy from the sun.

Solar cells may be divided into a variety of kinds depending upon materials used in a light-absorption layer, and the most currently available solar cell is a silicon solar cell. However, since silicon prices have been rising due to shortage of high purity silicon, a thin film type solar cell is drawing attention. The thin film type solar cell is fabricated to a thin thickness and thus contributes to less material consumption and lighter weight, thereby providing a wide application range. As a material for such a thin film solar cell, amorphous silicon, CdTe, CuInSe₂ (CIS), or CuIn₁₋ₓGaₓSe₂ (CIGS) has been widely researched.

A CIS or CIGS thin film is one of I-III-IV compound semiconductors and exhibits higher conversion efficiency than any other thin film solar cells fabricated in a laboratory. Particularly, it is expected to be a low-cost, high-efficiency solar cell which can replace silicon in that the solar cell can be fabricated in a thickness of 10 microns or less and has stable operation capabilities for a long-term use.

Generally, a solar cell including a CIGS thin film is fabricated on a soda lime glass substrate. In an initial development stage of CIGS solar cells, a Corning glass usable at high process temperature is used. However, after it was discovered that a soda lime glass substrate improves photoelectric conversion efficiency of the CIGS solar cell, the soda lime glass substrate has been essentially used.

This is because Na contained in the soda lime glass substrate improves efficiency of the CIGS solar cell. However, there are also drawbacks in that the soda lime glass substrate has a limitation in fabrication of a CIGS solar cell due to its low melting point and does not allow use of a flexible substrate formed of metal or polymer.

To solve these drawbacks, a method of forming a NaF layer between a rear electrode and a CIGS light-absorption layer and a method of supplying NaF through simultaneous vacuum-evaporation of NaF and a source material for a light-absorption layer in the process of depositing the CIGS light-absorption layer have been proposed. The separate formation of the NaF layer has a problem of additional manufacturing processes and degraded operation efficiency of a rear electrode due to the NaF layer formed between the light-absorption layer and the rear electrode. In addition, injection of NaF during the simultaneous vacuum-evaporation makes it difficult to form the light-absorption layer, which requires precise adjustment.

Recently, as shown in FIG. 9, a technique of constituting a rear electrode with two layers including a Na-added Mo electrode layer and a Na-free Mo electrode layer has been developed.

This technique is applied to a typical CIGS solar cell structure including a substrate 100, a rear electrode 200, a CIGS light-absorption layer 300, a buffer layer 400, a TCO front electrode 500, and a front anti-reflection layer 600. The technique includes a technique of forming a Na-added Mo electrode layer 210 and a Na-free Mo electrode layer 220 on lower and upper sides of the rear electrode 200 (see Korean Patent No. 10-0743923), a technique of the Na-added Mo electrode layer 210 and the Na-free Mo electrode layer 220 on the upper and lower sides of the rear electrode 200, a technique of the Na-added Mo electrode layer 210 between the Na-free Mo electrode layers 220, and the like.

According to this technique, the Mo electrode layer 220 is separately formed to compensate for high specific resistance of the Na-added Mo electrode layer 210. Here, as disclosed in Korean Patent No. 10-0743923, the formation of the Na-added Mo electrode layer is generally carried out in an Ar atmosphere at a pressure of 5˜15 mTorr or 5˜10 mTorr.

The technique of forming the rear electrode with two or three layers has a problem of complicated fabrication in that it includes a process of forming a Na-added Mo electrode layer and a Na-free Mo electrode layer, and it is difficult for the rear electrode to be adapted to a flexible substrate since the rear electrode has a multi-layer structure.

### PRIOR DOCUMENT

Korean Patent No. 10-0743923

### DISCLOSURE

### Technical Problem

The present invention has been conceived to solve such problems in the related art, and it is an object of the present invention to provide a CIGS solar cell having a flexible substrate formed of a single-layered low-specific resistance Na-added metal electrode layer.

### Technical Solution

In accordance with one aspect of the present invention, a CIGS solar cell having a flexible substrate based on improved supply of Na includes: a substrate formed of a flexible material; a rear electrode formed on the substrate; a CIGS light-absorption layer formed on the rear electrode; a buffer layer formed on the CIGS light-absorption layer; and a front electrode formed on the buffer layer, wherein the rear electrode is a single-layered Na-added metal electrode layer.

The rear electrode comprised of the single-layered Na-added metal electrode layer may have a specific resistance of 5×10⁻⁴ Ωcm or less.

As used herein, the CIGS is defined as an I-III-VI-group chalcopyrite-based compound semiconductor including CIS, CIGS, CIGSe, CIGSSe, and the like.

The inventors of the present invention propose a CIGS solar cell having a flexible substrate, which employs a single-layered Na-added metal electrode layer in order to supply Na to a light-absorption layer, unlike a conventional technique in which a rear electrode is formed to have a multilayer structure including a Na-added electrode layer and a Na-free electrode layer.

The flexible substrate may be formed of a polymer such as polyimide, or a metal foil such as a stainless steel foil.

A metal used in the metal electrode layer of the rear electrode may include Mo.

The substrate formed of a stainless steel foil exhibits excellent adhesion to the rear electrode. However, an adhesive layer may be optionally formed between the substrate and the rear electrode to improve adhesion between the substrate and the rear electrode.

In accordance with another aspect of the present invention, a method of forming a rear electrode of a CIGS solar cell having a flexible substrate based on improved supply of Na is provided. The method includes: forming a Na-added metal electrode layer by sputtering using a Na-doped metal target, wherein sputtering is carried out in an Ar atmosphere at a pressure of 0.5 mTorr to 2.5 mTorr, and an output density of 0.5 W/cm² to 5 W/cm² for a unit area of the target.

According to the present invention, a Na-added metal electrode layer is formed at a relatively low pressure in an Ar atmosphere by sputtering, unlike the related art in which a rear electrode is formed to have a multilayer structure including a Na-added Mo electrode layer. As a result, the Na-added metal electrode layer has low specific resistance and thus can be applied to a rear electrode of a CIGS solar cell even with a single electrode layer.

According to the invention, when the pressure for sputtering is decreased, a metal electrode layer having a specific resistance of about 5×10⁻⁴ Ωcm can be obtained even at an output density of 1.5 W/cm² or less, which is mainly used in a typical process of forming a rear electrode having a multilayer structure. Further, when sputtering is carried out at an output density of more than 1.5 W/cm², a metal electrode layer having lower specific resistance can be advantageously obtained within a shorter process time.

The metal target for the rear electrode may be composed of Mo. The present invention has effects that a Na-added Mo electrode layer, specific resistance of which is about 1/10th the specific resistance under typical sputtering conditions, can be formed under changed sputtering conditions. Consequently, the method according to the present invention can omit a process of forming a Na-free Mo electrode layer, thereby considerably reducing costs for forming the rear electrode.

In addition, according to the present invention, the rear electrode may be formed using the target doped with Na in an amount of 0.1% by weight (wt %) to 10 wt %. Although the doped amount of Na can vary depending upon a compositional ratio of respective elements and the thickness of the CIGS light-absorption layer, if the doped amount of Na exceeds 10 wt %, operational efficiency of the solar cell is not further improved, and if the doped amount of Na is excessively high, operational efficiency of the solar cell can be deteriorated. On the contrary, if the doped amount of Na is lower than 0.1 wt %, the light-absorption layer exhibits insignificant improvement in operation efficiency. Accordingly, the doped amount of Na is preferably within the range described above.

In accordance with a further aspect of the present invention, a method of fabricating a CIGS solar cell having a flexible substrate includes: preparing a flexible substrate; forming a rear electrode layer on the substrate; forming a CIGS light-absorption layer including CIGS on the rear electrode layer; forming a buffer layer on the CIGS light-absorption layer; and forming a front electrode on the buffer layer, wherein the formation of the rear electrode layer includes forming a single-layered Na-added metal electrode layer.

The formation of the single-layered Na-added metal electrode layer may include sputtering using a Na-doped target, wherein sputtering is carried out in an Ar atmosphere at a pressure of 0.5 mTorr to 2.5 mTorr and an output density of 0.5 W/cm² to 5 W/cm² for a unit area of the target.

The metal target used in sputtering may be composed of Mo. The present invention has effects that a Na-added Mo electrode layer, specific resistance of which is about 1/10th the specific resistance under typical sputtering conditions, can be formed under changed sputtering conditions. Consequently, the method according to the present invention can omit a process of forming a Na-free Mo electrode layer, thereby considerably reducing costs for forming the rear electrode.

According to the invention, when the pressure for sputtering is decreased, a metal electrode layer having a specific resistance of about 5×10⁻⁴ Ωcm can be obtained even at an output density of 1.5 W/cm² or less, which is mainly used in a typical process of forming a rear electrode having a multilayered structure. Further, when sputtering is carried out at an output density of more than 1.5 W/cm², a metal electrode layer having lower specific resistance can be advantageously obtained within a shorter process time.

In the rear electrode composed of the single-layered Na-added metal electrode layer formed by the method according to the present invention, the amount of Na supplied to the light-absorption layer may be optimized by controlling the amount of Na doped into the target in the range of 0.1 wt % to 10 wt %.

A process of removing a Na compound from the surface of the Na-added metal electrode layer may be further performed before the formation of the CIGS light-absorption layer, thereby solving problems of peeling-off of the light-absorption layer and deterioration in conversion efficiency of the solar cell due to the Na compound formed on the Na-added metal layer when the metal layer is exposed to air for a long time.

The removal of the Na compound may be carried out by cleaning the Na compound on the surface using a solvent. The solvent may include at least one selected from the group including water, ethanol, methanol, and glycerol in order to clean the Na compound including Na salts or Na hydroxides.

### Advantageous Effects

As set forth above, according to the present invention, a single-layered Na-added Mo electrode layer, specific resistance of which is about 1/10th the specific resistance under conditions of a process of forming a typical multilayer rear electrode, can be formed even by addition of Na, whereby a rear electrode of a CIGS solar cell having a flexible substrate can be formed in a single layer.

In addition, according to the present invention, the rear electrode is formed using a single Na-added metal electrode layer, thereby reducing the number of processes and costs in fabrication of the CIGS solar cell.

Further, the method according to the present invention further includes removal of a Na compound from the surface of the Na-added metal layer during exposure to air, thereby providing an effect of solving problems of peeling-off of a light-absorption layer and deterioration in conversion efficiency of the solar cell.

### DESCRIPTION OF DRAWINGS

The above and other objects, features, and advantages of the present invention will become apparent from the detailed description of the following embodiments in conjunction with the accompanying drawings, in which:

FIG. 1 is a schematic view of a CIGS solar cell having a flexible substrate based on improved supply of Na according to one embodiment of the present invention;

FIG. 2 shows an SIMS analysis result of a light-absorption layer of a CIGS solar cell fabricated in Example 4;

FIG. 3 shows an SIMS analysis result of a light-absorption layer of a CIGS solar cell fabricated in Comparative Example 4;

FIG. 4 shows a measurement result of Vickers hardness for an electrode layer formed in Example 5;

FIG. 5 shows a measurement result of Vickers hardness for an electrode layer formed in Comparative Example 5;

FIG. 6 shows a test result of adhesion between an electrode layer and a stainless steel substrate according to the present invention;

FIG. 7 is a SEM image showing a Na compound formed on a surface of a Na-added Mo electrode layer exposed to air;

FIG. 8 is a graph comparing conversion efficiencies between solar cells in which a Na compound-removal process was performed and a Na compound-removal process was not performed, respectively; and

FIG. 9 is a schematic view of a CIGS solar cell having a typical multilayer rear electrode.

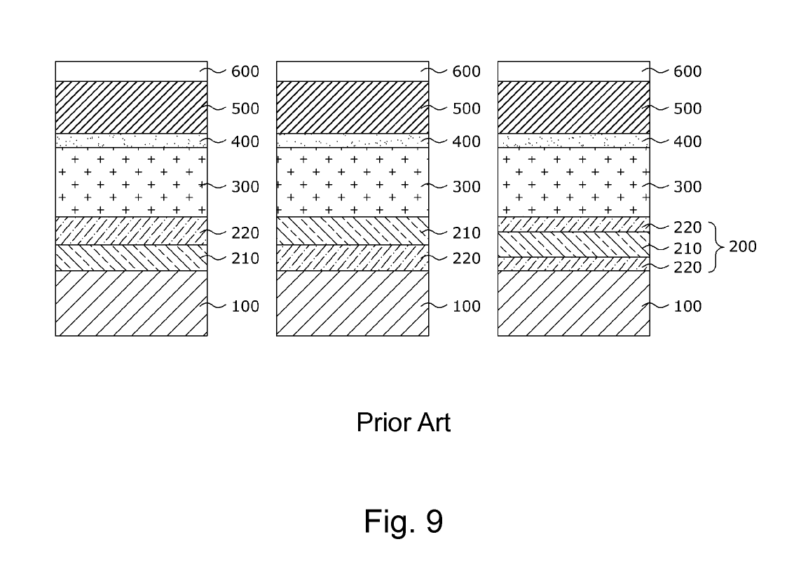

### MODE FOR INVENTION

Hereinafter, exemplary embodiments of the present invention will be described in detail with reference to the accompanying drawings.

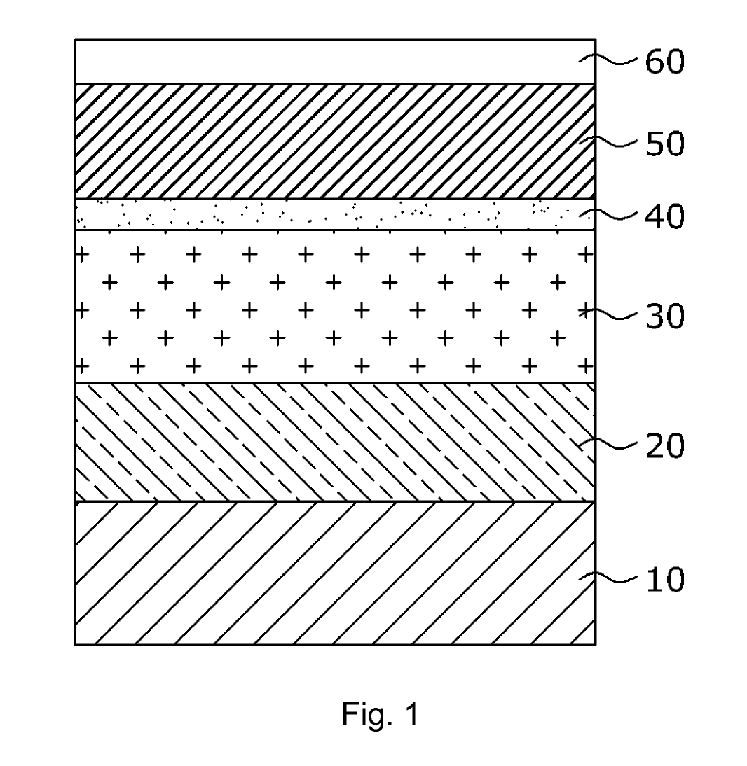

FIG. 1 is a schematic view of a CIGS solar cell having a flexible substrate based on improved supply of Na according to one embodiment of the present invention.

The CIGS solar cell having a flexible substrate according to this embodiment has a stack structure in which a rear electrode 20, a CIGS light-absorption layer 30, a buffer layer 40, a front electrode 50, and a front anti-reflection layer 60 are sequentially stacked on a flexible substrate 10. Here, the rear electrode 20 is composed only of a single-layered Na-added metal electrode layer.

Thus, a method of fabricating the CIGS solar cell having a flexible substrate according to this embodiment includes sequentially forming the rear electrode 20, the CIGS light-absorption layer 30, the buffer layer 40, the front electrode 50, and the front anti-reflection layer 60 on the flexible substrate 10. Here, the formation of the rear electrode 20 includes forming a single-layered Na-added metal electrode layer. Except for this feature, the other components of the CIGS solar cell can be formed by typical methods.

Hereinafter, the method of fabricating the CIGS solar cell having a flexible substrate will be described in more detail.

First, the flexible substrate 10 is prepared. The flexible substrate may be formed of any material. Particularly, the material may be a polymer such as polyimide, or a metal foil such as stainless steel. The flexible substrate 10 is prepared by sequentially cleaning a surface thereof with acetone, methanol, and distilled water.

If adhesion between the flexible substrate and the rear electrode is not good, the rear electrode can be formed after forming an adhesive layer or a texturing layer formed of metal oxide or nitride on the surface of the cleaned flexible substrate in order to improve adhesion. This process is apparent to those skilled in the art, and thus a detailed description thereof will be omitted herein.

Then, the rear electrode 20, which is a single-layered Na-added metal electrode layer, is formed by sputtering using a Na-doped target.

Specifically, the rear electrode is generally formed of Mo, and DC sputtering or RF sputtering is performed on a 0.1˜10 wt % Na-doped Mo target under conditions of an output density of 0.5 W/cm² to 5 W/cm² and a pressure of 0.5 mTorr to 2.5 mTorr in an Ar atmosphere.

Sputtering is performed at a relatively low pressure in an Ar atmosphere as compared with a typical process of forming a rear electrode having a multilayer structure including a Na-added Mo electrode layer, thereby reducing specific resistance of the Mo electrode layer. Specifically, a metal electrode layer having a specific resistance of about 5×10⁻⁴ Ωcm can be obtained even at an output density of 1.5 W/cm² or less, which is mainly used in the typical process of forming the multi-layered rear electrode. Further, if sputtering is carried out at an output density of more than 1.5 W/cm², a metal electrode layer having lower specific resistance can be advantageously obtained within a shorter process time. The rear electrode fabricated by the method of the present invention is composed of a single-layered Na-added Mo electrode layer, and has low specific resistance and high hardness. Thus, the rear electrode can be obtained only from the single-layered Na-added Mo electrode layer. A detailed description thereof will be described with reference to Examples.

Next, the CIGS light-absorption layer 30, the buffer layer 40, the front electrode 50, and the front anti-reflection layer 60 are sequentially formed on the rear electrode 20 by any typical methods in the art without limitation.

On the other hand, a process of removing a Na compound formed on the surface of the rear electrode 20 may be further performed before the CIGS light-absorption layer 30 is formed. This process removes the Na compound, which is formed on the surface of the Na-added Mo electrode layer forming the rear electrode during exposure of the electrode layer to air for a long time. The removal method may include any method capable of removing the Na compound. The Na compound formed on the surface of the Na-added Mo electrode layer may be Na hydrides, Na salts, or a combination thereof, and can be removed by cleaning the surface with at least one solvent selected from water, ethanol, methanol, and glycerol.

The method of forming the CIGS light-absorption layer 30 may employ both a non-vacuum method using a nanoparticle precursor or a solution precursor of a source material and a vacuum method such as 3-stage simultaneous vacuum evaporation which secures the highest performance in the art.

The buffer layer 40 is generally formed by forming a CdS layer through chemical bath deposition (CBD). Alternatively, a ZnS layer or ZnSe layer may be formed by CBD, an InₓSe_{y} layer or a ZnInₓSe_{y} layer may be formed by evaporation, or an InₓSe_{y} layer or a ZnSe layer may be formed by a CVD-based process.

The front electrode 50 may be generally formed by forming a TCO layer such as ZnO:Al or ITO through sputtering. Alternatively, the TCO layer may be formed by electron beam-evaporation or thermal-evaporation. Further, the front electrode may be composed only of the TCO layer, or otherwise may further include a grid electrode formed of Al or the like on the TCO layer.

The front anti-reflection layer 60 may be formed by forming MgF₂ through thermal-evaporation or atomic layer deposition (ALD), or by forming Al₂O₃ through ALD.

In the method of fabricating the CIGS solar cell having a flexible substrate and the CIGS solar cell fabricated by the method, the rear electrode is formed by a single process of forming a Na-added Mo electrode layer while Na added to the rear electrode in the fabrication process is diffused into the CIGS light-absorption layer, thereby improving conversion efficiency of a solar cell while considerably reducing process costs by omitting additional processes or equipment.

Hereinafter, specific resistance, diffusion of Na ions, mechanical hardness, and adhesion of a stainless steel substrate to the Na-added Mo electrode layer prepared according to the embodiment of the present invention will be confirmed through Examples and Comparative Examples.

### Specific Resistance

### Example 1

A single-layered Na-added Mo electrode layer was formed through DC sputtering for 25 minutes using a 1.5 wt % Na-doped Mo target in an Ar atmosphere at a pressure of 0.5 mTorr and an output density of up to 4 W/cm² for the target.

### Example 2

A single-layered Na-added Mo electrode layer was formed through DC sputtering for 60 minutes using a 1.5 wt % Na-doped Mo target in an Ar atmosphere at a pressure of 0.5 mTorr and an output density of up to 1 W/cm² for the target.

### Example 3

A single-layered Na-added Mo electrode layer was formed through RF sputtering for 30 minutes using a 3 wt % Na-doped Mo target in an Ar atmosphere at a pressure of 1 mTorr and an output density of up to 3 W/cm² for the target.

### Comparative Example 1

A Na-added Mo electrode layer was formed through DC sputtering for 32 minutes using a 1 wt % Na-doped Mo target in an Ar atmosphere at a pressure of 10 mTorr and an output density of up to 1 W/cm² for the target.

### Comparative Example 2

A Na-added Mo electrode layer was formed through DC sputtering for 34 minutes using a 1.5 wt % Na-doped Mo target in an Ar atmosphere at a pressure of 10 mTorr and an output density of up to 1 W/cm² for the target.

### Comparative Example 3

A Na-added Mo electrode layer was formed through DC sputtering for 50 minutes using a 3 wt % Na-doped Mo target in an Ar atmosphere at a pressure of 5 mTorr and an output density of up to 1.5 W/cm² for the target.

In Comparative Examples, sputtering was performed in an Ar atmosphere at a pressure of 5˜15 mTorr and an output density of 1˜1.5 W/cm² for the target, which correspond to conditions for forming a Na-added Mo electrode layer in the related art to form a rear electrode having a multilayer structure, and differences in process time between Comparative Examples and Examples were controlled to form Mo electrode layers having a similar thickness, by taking into account differences in output densities for the target and process pressures.

A result of measuring specific resistance of the Mo electrode layers of Examples and Comparative Examples is shown in Table 1.

TABLE 1

| | Sample No. | | | | | |
|---|---|---|---|---|---|---|
| | | | | Comparative | Comparative | Comparative |
| | Example 1 | Example 2 | Example 3 | Example 1 | Example 2 | Example 3 |
| Specific | 1.16 | 2.24 | 2.78 | 50.4 | 31.32 | 29.35 |
| Resistance | | | | | | |
| (×10⁻⁴ Ωcm) | | | | | | |

As shown in Table 1, the Mo electrode layers of Comparative Examples had high specific resistance not suitable for a rear electrode of a solar cell as a single layer, whereas the Mo electrode layers of Examples had specific resistances, which are about 1/10th the specific resistance of the Mo electrode layers of Comparative Examples.

Furthermore, the specific resistances of the Mo electrode layers of Examples are lower than 0.5˜1×10⁻³ Ωcm, that is, the specific resistance of ZnO:Al, which has been used as a transparent electrode of a solar cell in recent years, and this result indicates that the Mo electrode layers of Examples can be applied to a rear electrode of a solar cell as a single layer.

### Diffusion of Na Ions

### Example 4

A single-layered Na-added Mo electrode layer was formed on a stainless steel substrate through DC sputtering for 30 minutes using a 1.5 wt % Na-doped Mo target in an Ar atmosphere at a pressure of 0.5 mTorr and an output density of up to 3 W/cm² for the target. Then, a CIGS light-absorption layer was formed on the Na-added Mo electrode layer by simultaneous vacuum evaporation, and a CdS layer was formed as a buffer layer by a CBD process, and finally a front electrode formed of a ZnO:Al material was formed by DC sputtering.

### Comparative Example 4

A Na-free Mo electrode layer was formed on a soda lime glass substrate using a Mo target. Then, a CIGS light-absorption layer, a CdS layer, and a ZnO:Al front electrode were formed on the Na-free Mo electrode layer under the same conditions as in Example 4.

Secondary ion mass spectrometer (SIMS) analysis was performed in order to determine an amount of Na ions diffused into the CIGS light-absorption layer in the process of fabricating the CIGS solar cell by the aforementioned method.

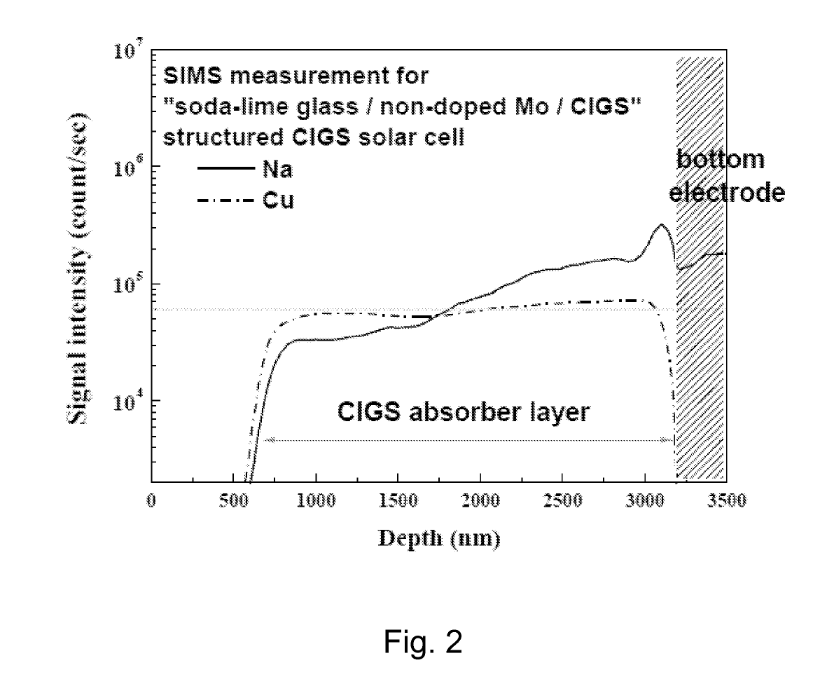

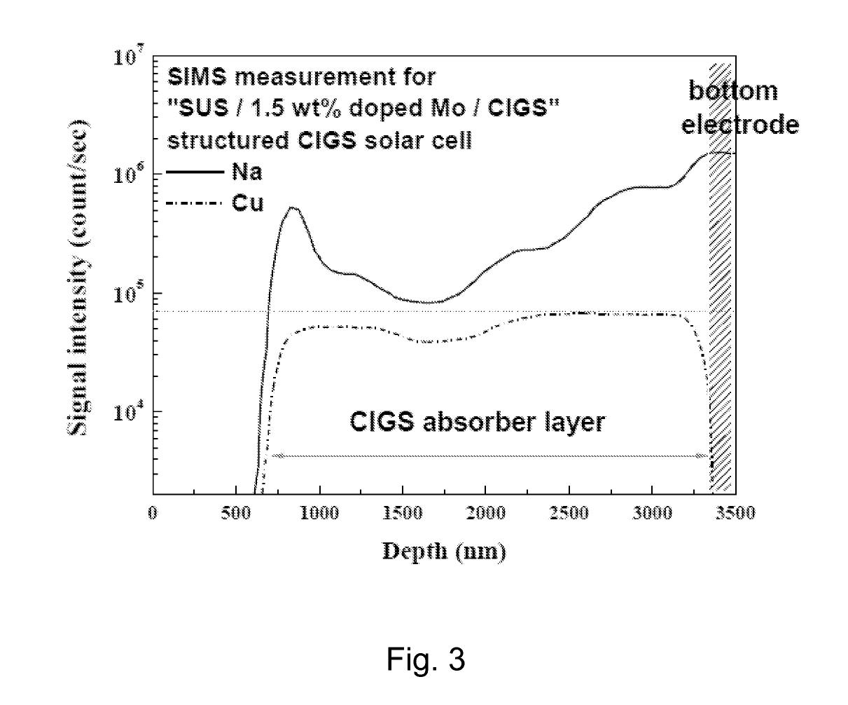

FIG. 2 shows a SIMS analysis result of a light-absorption layer of a CIGS solar cell fabricated in Example 4, and FIG. 3 shows an SIMS analysis result of a light-absorption layer of a CIGS solar cell fabricated in Comparative Example 4.

Since the CIGS light-absorption layers of Example 4 and Comparative Example 4 were formed under the same conditions, the analysis result exhibited substantially similar Cu-distribution but much more Na was detected in Example 4.

Accordingly, it could be seen that, in the examples in which the rear electrode composed of the Na-added Mo electrode layer was used, a higher or at least similar amount of Na was diffused than in the case in which a soda lime glass substrate was used.

### Mechanical Hardness

### Example 5

A single-layered Na-added Mo electrode layer was formed through DC sputtering using a 3 wt % Na-doped Mo target in an Ar atmosphere at a pressure of 1 mTorr and an output density of up to 3 W/cm² for the target, and after one week, hardness of the electrode layer was measured using a Vickers hardness tester.

### Comparative Example 5

A bottom electrode layer was formed through DC sputtering using a Na-not-doped Mo target in an Ar atmosphere at a pressure of 10 mTorr and an output density of up to 1.3 W/cm² for the target, an upper electrode layer was formed through DC sputtering in an Ar atmosphere at a pressure of 1 mTorr and an output density of up to 5 W/cm² for the target, and after one week, hardness of the electrode layers was measured using a Vickers hardness tester.

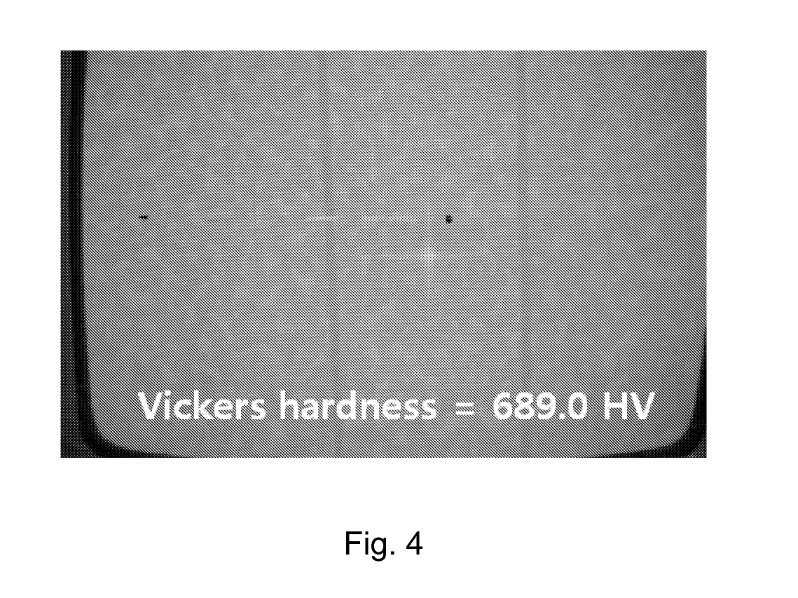

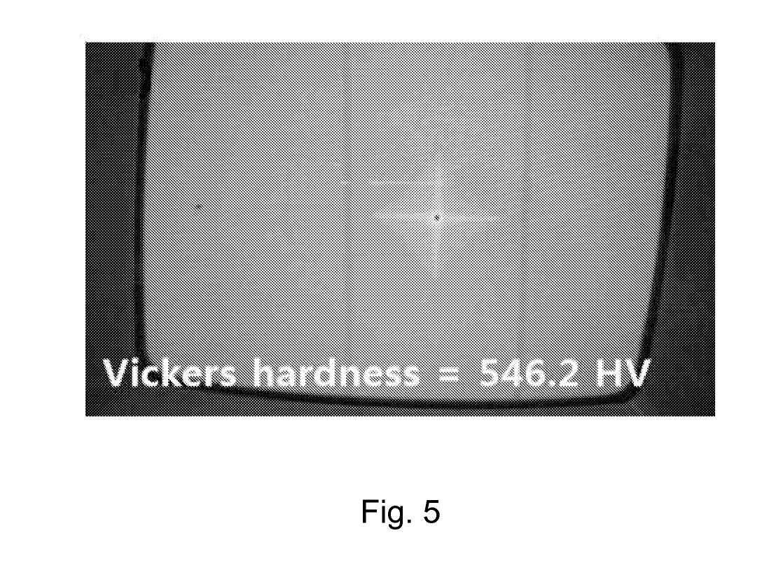

FIG. 4 shows a measurement result of Vickers hardness for an electrode layer formed in Example 5, and FIG. 5 shows a measurement result of Vickers hardness for an electrode layer formed in Comparative Example 5.

The electrode layer of Comparative Example 5 was formed by a 2-stage Mo rear electrode-forming method which is generally used in manufacture of the CIGS solar cell using a soda lime glass substrate. In addition, Vickers hardness measured on the surface of the upper electrode layer was 546.2 HV, whereas the Vickers hardness measured on the Na-added Mo electrode layer of Example 5 was 689.0 HV. Thus, it could be seen that the Na-added Mo electrode layers of the inventive examples had higher hardness than those of the comparative examples.

<Adhesion to Stainless Steel Foil Substrate>

A single-layered Na-added Mo electrode layer was formed on a stainless steel substrate, which is a metal foil flexible substrate, through DC sputtering using a 1.5 wt % Na-doped Mo target in an Ar atmosphere at a pressure of 0.5 mTorr and an output density of up to 2 W/cm² for the target, and adhesion between the Mo electrode layer and the stainless steel substrate was tested using a Scotch-tape method according to ASTM-D3359.

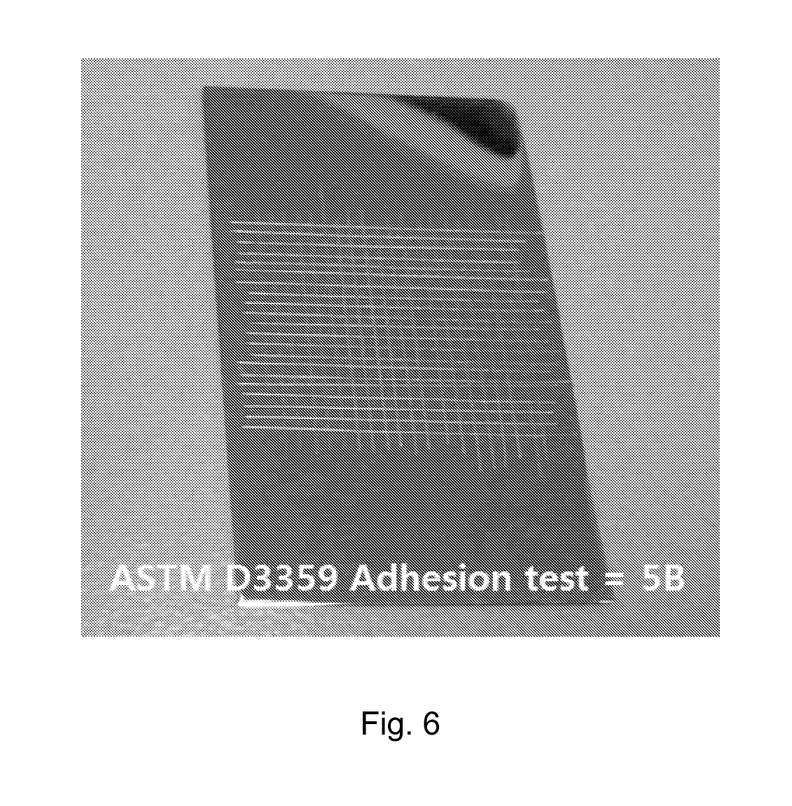

FIG. 6 shows a test result of adhesion between the electrode layer and the stainless steel substrate prepared in this example.

In FIG. 6, the Na-added Mo electrode layer of this example was rated to 5B, which is the highest score according to ASTM-D3359. Thus, it could be seen that adhesion of the Na-added Mo electrode layer to the stainless steel substrate was excellent.

Therefore, it could be seen that the single-layered Na-added Mo electrode layer of this example could be formed on the stainless steel foil substrate, which is a flexible substrate, without providing a separate adhesive layer.

<Effects of Formation and Removal of Surface Na Compound>

In the process of fabricating the CIGS solar cell by sequentially forming the light-absorption layer, the buffer layer, and the front electrode on the single-layered Na-added Mo electrode layer as a rear electrode, peeling-off of the light-absorption layer and lower-than-expected conversion efficiency of the fabricated solar cell were partially found. These phenomena were also found in part in the related art in which a CIGS solar cell is fabricated using a multi-layered rear electrode.

As a result of studies on these problems, it was identified that these phenomena occurred since the Na-added Mo electrode layer was exposed to air for a long time. Long exposure to air occurred after the Na-added Mo electrode layer was formed in the process of forming the CIGS light-absorption layer and in the course of controlling the entire process in manufacture of the CIGS solar cell. In this case, a Na compound was formed on the surface of the Na-added Mo electrode layer, causing peeling-off of the light-absorption layer and deterioration in conversion efficiency of a solar cell.

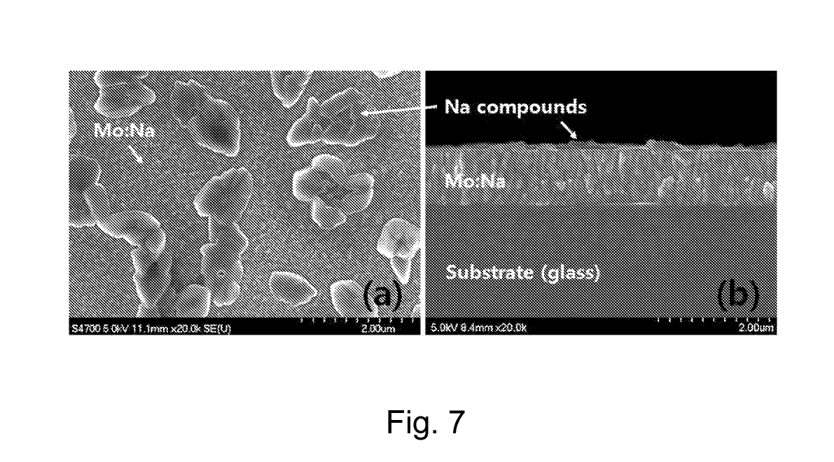

FIG. 7 is a SEM image showing a Na compound formed on a surface of a Na-added Mo electrode layer exposed to air.

A single-layered Na-added Mo electrode layer was formed through DC sputtering using a 10 at % (about 3.125 wt %) Na-doped Mo target in an Ar atmosphere at a pressure of 0.5 mTorr and an output density of up to 4 W/cm² for the target, and the surface of the electrode layer was photographed after one week-exposure to air. It could be seen that a Na compound was formed on the surface of the Na-added Mo electrode layer. As a result of EDS analysis for the Na compound, a great amount of O and C and a small amount of Mo or the like were detected in addition to Na. Here, since H atoms cannot be detected by EDS analysis, they were not detected. However, since the Na compound is a compound formed by reaction with air, it was assumed that a hydroxide including H was formed. Such a Na salt and a Na hydroxide can be removed by a solvent, which may include water, ethanol, methanol, glycerol, or a combination thereof. In the present embodiment, although the Na compound formed on the surface of the Na-added Mo electrode layer is qualitatively analyzed after extended exposure to air, such a Na compound is generated even when the Na-added Mo electrode layer is shortly exposed to air for about a few minutes. Such a short exposure does not cause peeling-off of the CIGS layer, but can induce deterioration in conversion efficiency of a solar cell.

In this example, after exposure to air, the single-layered Na-added Mo electrode layer, which was formed on the stainless steel flexible substrate through DC sputtering using a 5 at % (about 1.563 wt %) Na-doped Mo target, was surface-cleaned using deionized (DI) water, thereby removing the Na compound from the surface of the electrode layer. Then, the CIGS light-absorption layer, the buffer layer, and the front electrode were formed on the single-layered Na-added Mo electrode layer formed as a rear electrode, thereby forming a CIGS solar cell. Further, as a Comparative Example, a CIGS solar cell was fabricated by the same process as above except that the process of removing the Na compound was eliminated.

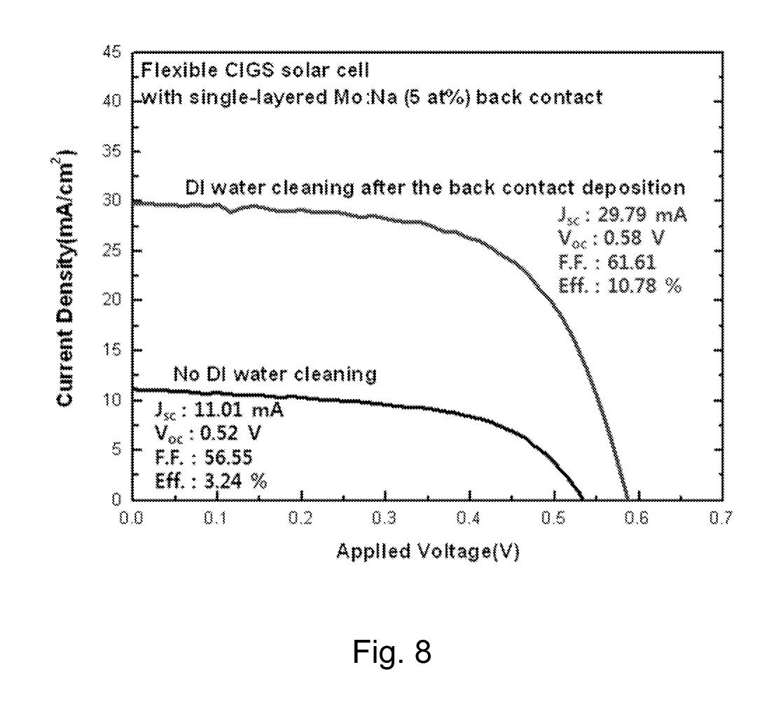

FIG. 8 is a graph comparing conversion efficiencies between solar cells in which a Na compound-removal process was performed and a Na compound-removal process was not performed, respectively.

As shown in FIG. 8, the solar cell of Comparative Example, which was not subjected to the process of removing the Na compound using DI water, exhibited a lower-than-expected conversion efficiency of 3.24%, whereas the solar cell of Example, which was subjected to the process of removing the Na compound using DI water, exhibited a conversion efficiency of 10.78%.

Therefore, it can be seen that, in the case that the Na-added metal electrode layer is applied to the rear electrode, peeling-off of the light-absorption layer and deterioration in conversion efficiency can be prevented by the addition of the process of removing the Na compound formed on the surface of the rear electrode due to exposure to air, thereby considerably improving fabrication efficiency and conversion efficiency of a solar cell.

Although some embodiments have been described above, it should be understood that these embodiments are given by way of illustration only, and that various modifications, variations, and alterations can be made without departing from the spirit and scope of the present invention. The scope of the present invention should be limited only by the accompanying claims and equivalents thereof.

1. A CIGS solar cell having a flexible substrate based on improved supply of Na, comprising:
a substrate formed of a flexible material;
a rear electrode formed on the substrate;
a CIGS light-absorption layer formed on the rear electrode;
a buffer layer formed on the CIGS light-absorption layer; and
a front electrode formed on the buffer layer,
wherein the rear electrode comprises a single-layered Na-added metal electrode layer.

2. The CIGS solar cell according to claim 1, wherein the rear electrode has a specific resistance of 5×10⁻⁴ Ωcm or less.

3. The CIGS solar cell according to claim 1, wherein the substrate is formed of a polymer including polyimide, or a metal foil including a stainless steel foil.

4. The CIGS solar cell according to claim 1, wherein the metal electrode layer forming the rear electrode comprises a Mo electrode layer.

5. The CIGS solar cell according to claim 1, wherein an adhesive layer is additionally formed between the substrate and the rear electrode to improve adhesion between the substrate and the rear electrode.

6. A method of forming the rear electrode of the CIGS solar cell according to claim 1, the method comprising:
forming a single-layered Na-added metal electrode layer by sputtering using a Na-doped metal target,
wherein sputtering is carried out in an Ar atmosphere at a pressure of 0.5 mTorr to 2.5 mTorr and an output density of 0.5 W/cm² to 5 W/cm² for a unit area of the target.

7. The method according to claim 6, wherein sputtering is carried out at an output density of more than 1.5 W/cm² to 5 W/cm² or less.

8. The method according to claim 6, wherein the metal target is composed of Mo.

9. The method according to claim 8, wherein Na is doped in an amount of 0.1% to 10 wt % into the metal target.

10. A method of fabricating a CIGS solar cell according to claim 1, comprising:
preparing a flexible substrate;
forming a rear electrode layer on the substrate;
forming a CIGS light-absorption layer including CIGS on the rear electrode layer;
forming a buffer layer on the CIGS light-absorption layer; and
forming a front electrode on the buffer layer,
wherein the formation of the rear electrode layer comprises forming a single-layered Na-added metal electrode layer.

11. The method according to claim 10, wherein the formation of the single-layered Na-added metal electrode layer is carried out by sputtering using a Na-doped target.

12. The method according to claim 11, wherein sputtering is carried out in an Ar atmosphere at a pressure of 0.5 mTorr to 2.5 mTorr and an output density of 0.5 W/cm² to 5 W/cm² for a unit area of the target.

13. The method according to claim 12, wherein sputtering is carried out under conditions of an output density from 2 W/cm² to 5 W/cm² for a unit area of the target.

14. The method according to claim 12, wherein the metal target is composed of Mo.

15. The method according to claim 12, wherein Na is doped in an amount of 0.1% to 10 wt % into the metal target.

16. The method according to claim 10, further comprising: removing a Na compound from the surface of the Na-added metal electrode layer before the formation of the CIGS light-absorption layer.

17. The method according to claim 16, wherein removal of the Na compound is carried out by cleaning the Na compound using a solvent.

18. The method according to claim 17, wherein the solvent comprises at least one selected from among water, ethanol, methanol, and glycerol.
